(19) United States
(12) Patent Application Publication
(10) Pub. No.: US 2006/0139900 A1
(43) Pub. Date: Jun. 29, 2006

(54) Expansion card having improved circuit layout and a method for redefining terminal connections of the expansion card

(75) Inventor: Heng-Chen Kuo, Tu-Cheng (TW)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/311,977

(22) Filed: Dec. 19, 2005

(30) Foreign Application Priority Data
Dec. 24, 2004 (CN) 200410091862.6

(51) Int. Cl. H05K 7/08; H05K 7/10; H05K 7/02; H05K 7/06

(52) U.S. Cl. 361/760

(57) ABSTRACT

An expansion card (1) includes a circuit board. A plurality of terminal circuits (101) is located on the circuit board, and a plurality of electrically conductive first vias is defined in the circuit board, and is electrically connected with the terminal circuits respectively. A plurality of main circuits (103) is located on the circuit board, and a plurality of electrically conductive second vias is defined in the circuit board, and is electrically connected with the main circuits respectively. A plurality of resistors is removably connected between corresponding main circuits and terminal circuits. A method for redefining terminal connections of the expansion card is also provided.

### BACKGROUND OF THE INVENTION

1. Field of the Invention

The present invention relates to expansion cards of computers, and a method for redefining terminal connections of an expansion card.

2. General Background

In designing an expansion card, for example a smart network card, pins of the expansion card are electrically connected with circuitry thereof, for conducting electrical signals and achieving a desired function or result. Each of the pins can be defined to conduct a unique electrical signal. Once the expansion card is produced, the pins are permanently assigned to conduct a specified kind of electrical signal. If the function of a particular pin needs to be redefined, the relevant portion of the circuitry associated with that pin must first be identified. However, the circuitry is continuously formed, thereby making it difficult to locate which portion of the circuitry is associated with the pin of interest. Even when the target portion of the circuitry has been identified, it is generally difficult to break off the connection of the pin from that portion of the circuitry and reconnect the pin to another desired portion of the circuitry.

What is desired, therefore, is an expansion card which facilitates redefining terminal connections thereof. What is also desired is a method for readily redefining terminal connections of an expansion card.

### SUMMARY

In one preferred embodiment, an expansion card includes a circuit board defining at least two electrically conductive first vias and at least one electrically conductive second via; at least two terminal circuits located on the circuit board, the terminal circuits electrically connected with the first vias respectively; at least one main circuit located on the circuit board, the main circuit electrically connected with the second via; and at least one resistor removably connected between the main circuit and one of the terminal circuits.

A method for redefining terminal connections of an expansion card includes the steps of: removing a first resistor connected between a first main circuit and a first terminal circuit of the expansion card; providing a first electrical conductor; and electrically connecting the first electrical conductor between an electrically conductive second via electrically connected with the first main circuit and an electrically conductive first via electrically connected with a second terminal circuit which needs to be redefined.

Other advantages and novel features will become more apparent from the following detailed description of a preferred embodiment when taken in conjunction with the accompanying drawings, in which:

### BRIEF DESCRIPTION OF THE DRAWINGS

FIGS. 1 and 2 are schematic, plan views of an expansion card in accordance with a preferred embodiment of the present invention, respectively showing opposite sides thereof; and

FIGS. 3, 4, and 5 are schematic, plan views of the expansion card of the preferred embodiment, showing terminals thereof redefined.

### DETAILED DESCRIPTION OF THE EMBODIMENT

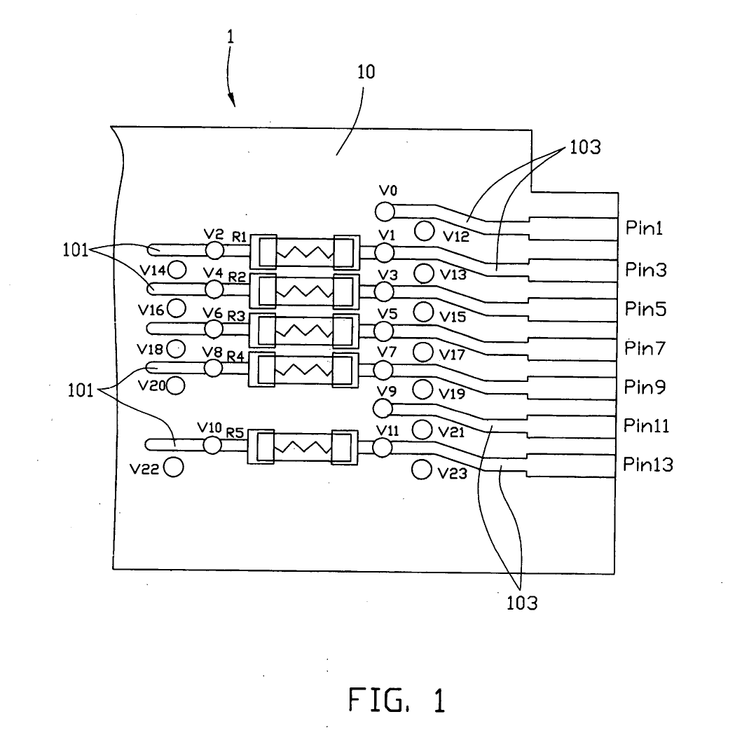

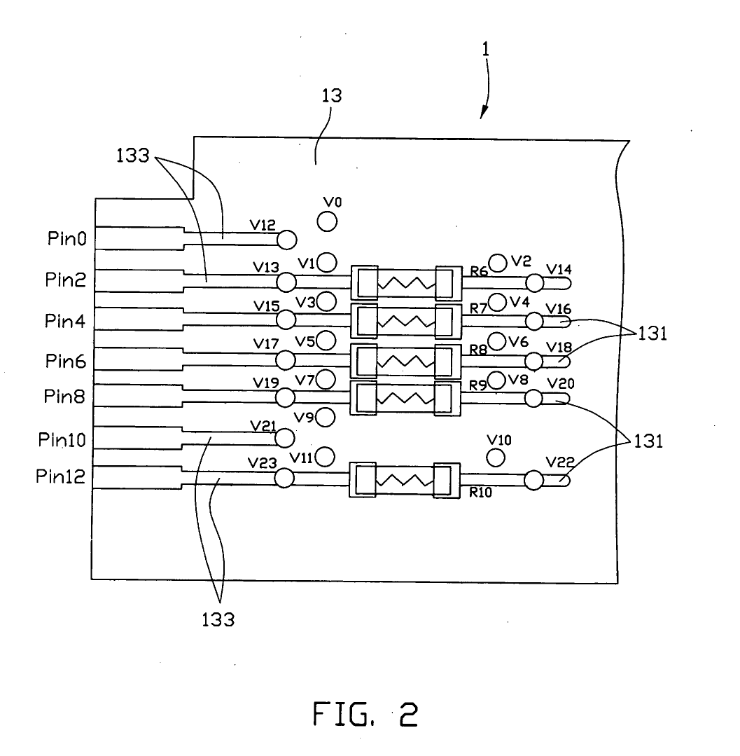

FIGS. 1 and 2 show an electronic part like an expansion card 1 in accordance with a preferred embodiment of the present invention. The expansion card 1 includes a circuit board, and 14 terminals respectively labeled as pin0˜pin13 on opposite sides 10, 13 of the circuit board, each side having 7 terminals arranged thereon. The expansion card 1 can be, for example, a network card or a video card. The terminals are often referred to as gold fingers by a person skilled in the art.

Referring particularly to FIG. 1, the side 10 includes five main circuits 101, five resistors respectively labeled as R1˜R5, and seven terminal circuits 103 electrically connected with the terminals pin1, pin3, pin5, pin7, pin9, pin11, and pin13. The resistors R1, R2, R3, R4, and R5 used as removable electrically connection are respectively removably electrically connected between the main circuits 101 and five of the terminal circuits 103 respectively electrically connected with the terminals pin3, pin5, pin7, pin9, and pin13. Terminals pin1 and pin11 are not assigned any function. Five first electrically conductive vias V1, V3, V5, V7, and V11 are defined through the circuit board, and are respectively electrically connected with the terminal circuits 103 correspondingly connected with the terminals pin3, pin5, pin7, pin9, and pin13. Five second electrically conductive vias V2, V4, V6, V8 and V10 are defined through the circuit board, and are respectively electrically connected with the main circuits 101. An impedance of each of the resistors R1, R2, R3, R4, and R5 is zero ohms. Two third electrically conductive vias V0 and V9 are defined through the circuit board, and are respectively electrically connected with the terminal circuits 103 correspondingly connected with the terminals pin1 and pin11.

Referring particularly to FIG. 2, side 13 includes five main circuits 131, five resistors respectively labeled as R6˜R10, and seven terminal circuits 133 electrically connected with the terminals pin0, pin2, pin4, pin6, pin8, pin10, and pin12. The resistors R6, R7, R8, R9, and R10 are respectively removably electrically connected between the main circuits 131 and five of the terminal circuits 133 respectively connected with the terminals pin13, pin15, pin17, pin19, and pin23. Terminals pin0 and pin10 are not connected to the main circuits and are not assigned any function. Five first electrically conductive vias V13, V15, V17, V19, and V23 are defined through the circuit board, and are respectively electrically connected with the terminal circuits 133 correspondingly connected with the terminals pin2, pin4, pin6, pin8, and pin12. Five second electrically conductive vias V14, V16, V18, V20, and V22 are defined through the circuit board, and are respectively electrically connected with the main circuits 131. An impedance of each of the resistors R6, R7, R8, R9, and R11 is zero ohms. Two third electrically conductive vias V12 and V21 are defined through the circuit board, and are respectively electrically connected with the terminal circuits 103 correspondingly connected with the terminals pin0 and pin10.

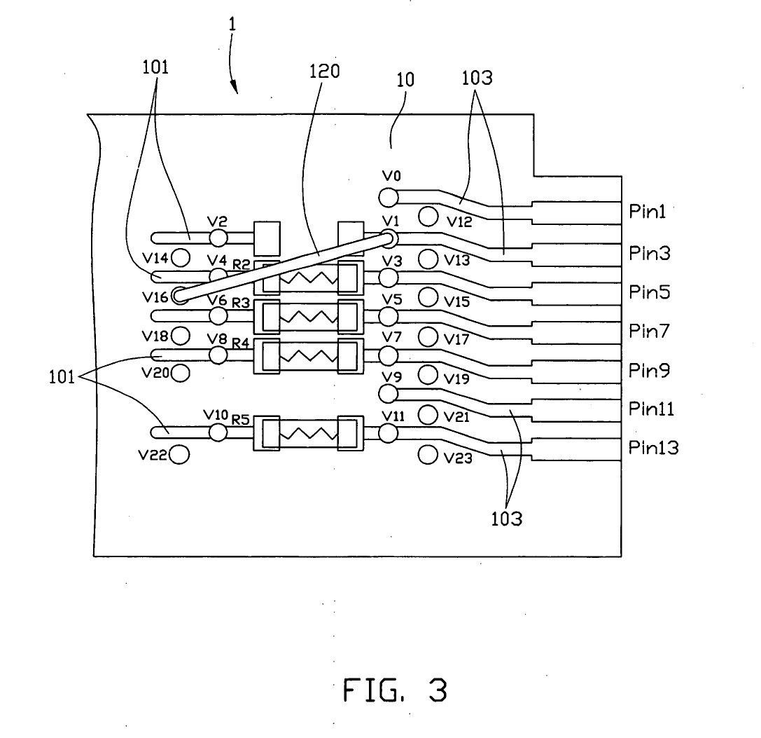

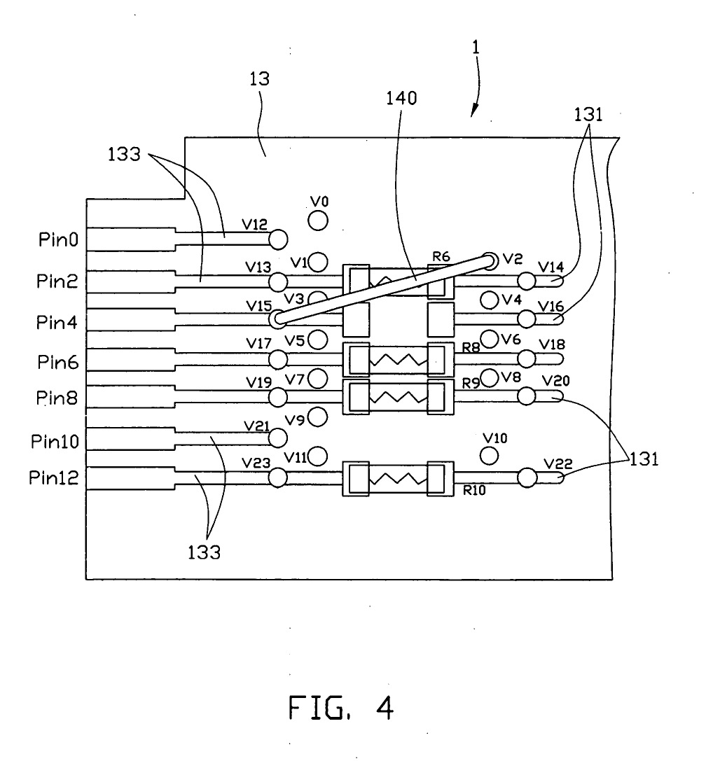

Referring to FIGS. 3 and 4, to redefine the function of a terminal, for example, to exchange functions of the terminals pin3, pin4 respectively located on the two sides 10, 13 of the expansion card 1, the resistors R1, R7 are removed from the sides 10, 13 respectively, the terminal circuit 103 connected with the terminal pin3 is broken from the main circuit 101, and the terminal circuit 133 connected with the terminal pin4 is broken from the main circuit 131. A first electrical conductor 120, for example a copper line, electrically connects the terminal pin3 with the main circuit 131 corresponding to the terminal pin4, with two free ends of the electrical conductor 120 being soldered in the first and second vias V1, V16. A second electrical conductor 140, for example a copper line, electrically connects the terminal pin4 with the main circuit 101 corresponding to the terminal pin3, with two free ends of the electrical conductor 140 being soldered in the first and second vias V15, V2. The functions of terminals pin3, pin4 are thus exchanged.

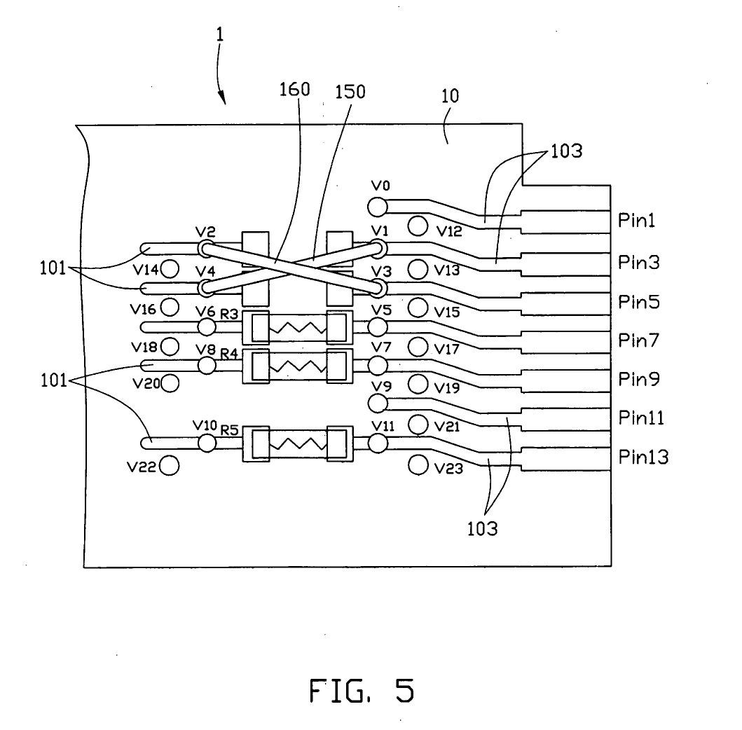

FIG. 5 shows how to redefine functions of the terminals pin3, pin5 both located on the side 10. Resistors R1, R2 are removed from the side 10. A third electrical conductor 150, for example a copper line, electrically connects the terminal pin3 with the main circuit 101 corresponding to the terminal pin5, with two free ends of the electrical conductor 150 being soldered in the first and second vias V1, V4. A fourth electrical conductor 160, for example a copper line, electrically connects the terminal pin5 with the main circuit 101 corresponding to the terminal pin3, with two free ends of the electrical conductor 160 being soldered in the first and second vias V3, V2.

It is believed that the present embodiment and its advantages will be understood from the foregoing description, and it will be apparent that various changes may be made thereto without departing from the spirit and scope of the invention or sacrificing all of its material advantages, the embodiment and examples hereinbefore described merely being one preferred or exemplary embodiment with exemplary detail.

What is claimed is:

1. An expansion card, comprising:
a circuit board defining at least two electrically conductive first vias and at least one electrically conductive second via;
at least two terminal circuits located on the circuit board, the terminal circuits electrically connected with the first vias respectively;
at least one main circuit located on the circuit board, the main circuit electrically connected with the second via; and
at least one resistor removably connected between the main circuit and one of the terminal circuits.

2. The expansion card as claimed in claim 1, further comprising at least two terminals electrically connected with the terminal circuits respectively.

3. The expansion card as claimed in claim 1, wherein the circuit board comprises a pair of opposite sides, and the terminal circuits, the main circuit, and the resistor are arranged on one of the sides.

4. The expansion card as claimed in claim 1, wherein an impedance of the resistor is zero ohms.

5. The expansion card as claimed in claim 1, wherein the first vias and the second via are defined through the circuit board.

6. A method for redefining terminal connections of an expansion card, the method comprising the steps of:
removing a first resistor connected between a first main circuit and a first terminal circuit of the expansion card;
providing a first electrical conductor; and
electrically connecting the first electrical conductor between an electrically conductive second via electrically connected with the first main circuit and an electrically conductive first via electrically connected with a second terminal circuit which needs to be redefined.

7. The method as claimed in claim 6, further comprising the steps of: removing a second resistor connected between a second main circuit and the second terminal circuit, providing a second electrical conductor, and electrically connecting the second electrical conductor between an electrically conductive first via electrically connected with the first terminal circuit and an electrically conductive second via electrically connected with the second main circuit.

8. The method as claimed in claim 7, wherein the first electrical conductor comprises two free ends respectively soldered in the first via of the second terminal circuit and the second via of the first main circuit.

9. The method as claimed in claim 8, wherein the second electrical conductor comprises two free ends respectively soldered in the first via of the first terminal circuit and the second via of the second main circuit.

10. The method as claimed in claim 9, wherein each of the first and second electrical conductors is a copper line.

11. A method for redefining terminal connections of an electronic part, comprising the steps of:
assigning a plurality of predefined terminals of an electronic part to a plurality of corresponding main circuits of said electronic part respectively;
setting up a removable electrical connection between each of said plurality of terminals and corresponding each of said plurality of main circuit so that said each of said plurality of terminals and said corresponding each of said plurality of main circuit are capable of being electrically disconnected by removing said connection;
providing an electrically connecting means for said each of said plurality of terminals and said each of said plurality of main circuits; and
reassigning a user-selected terminal out of said plurality of terminals to a newly corresponding main circuit out of said plurality of main circuits by means of disconnecting said electrical connection between said user-selected terminal and an originally-assigned corresponding main circuit, and electrically connecting said user-selected terminal with said newly corresponding main circuit via said electrically connecting means thereof.

12. The method as claimed in claim 11, wherein said electrical connection is a removable resistor electrically connectable between said each of said plurality of terminals and said corresponding each of said plurality of main circuits.

13. The method as claimed in claim 11, wherein said electrically connecting means is a via electrically connectable with respective one of said each of said plurality of terminals and said corresponding each of said plurality of main circuits.
